(19) United States
(12) Patent Application Publication
(10) Pub. No.: US 2008/0258273 A1
(43) Pub. Date: Oct. 23, 2008

(54) Package Structure With Flat Bumps For Electronic Device and Method of Manufacture the Same

(75) Inventors: Jerry Liang, Xinzhu County (TW); Jieren Xie, Jiangsu (CN); Xinchao Wang, Jiangsu (CN); Xiekang Yu, Jiangsu (CN); Yujuan Tao, Jiangsu (CN); Rongfu Wen, Jiangsu (CN); Fushou Li, Jiangsu (CN); Zhengwei Zhou, Jiangsu (CN); Da Wang, Jiangsu (CN); Haibo Ge, Jiangsu (CN); Qiang Zheng, Jiangsu (CN); Zhen Gong, Jiangsu (CN); Weijun Yang, Jiangsu (CN)

Correspondence Address: HESLIN ROTHENBERG FARLEY & MESITI PC, 5 COLUMBIA CIRCLE, ALBANY, NY, 12203, US

(73) Assignee: Jiangsu Changjiang Electronics Technology Co., Ltd, Jiangyin (CN)

(21) Appl. No.: 11/910,878

(22) PCT Filed: Apr. 6, 2006
(86) PCT No.: PCT/CN2006/000607

§ 371 Date: May 16, 2008

(30) Foreign Application Priority Data
Apr. 7, 2005 (CN) 200510038818.3
May 27, 2005 (CN) 200510040261.7
May 27, 2005 (CN) 200510040262.1
Jul. 2, 2005 (CN) 200510041043.5
Jul. 2, 2005 (CN) 200510041044.X
Jul. 5, 2005 (CN) 200510041069.X
Jul. 5, 2005 (CN) 200510041070.2
Jul. 18, 2005 (CN) 200510041274.6
Jul. 18, 2005 (CN) 200510041275.0

(51) Int. Cl. H01L 23/495; H01L 21/56

(52) U.S. Cl. 257/666; 438/114; 257/E23.031; 257/E21.502

(57) ABSTRACT

The invention discloses an ultra thin package structure of leadless electronic device and the packaging method, and includes lead support base adjacent to the chip support base; chip mounted on the chip support base; wires bonded between chip and lead support base; the molded body encapsulating the top surface and side surface of the chip support base, small protrusions of the chip support base and lead support base below the molded body; in the individual package, the number of the chip support base island can be one or more, the lead pins can be arrayed at one side of the island, also can be arrayed at two sides or three sides of the island, one or two rows of lead pins can be located around the island.

### CROSS-REFERENCE TO RELATED APPLICATIONS

This application is a §371 filing of PCT application CN2006/000607 which claims priority from Chinese application 200510038818.3 filed on Apr. 7, 2005, Chinese application 200510040262.1 filed on May 27, 2005, Chinese application 200510040261.7 filed on May 27, 2005, Chinese application 200510041044.X filed on Jul. 2, 2005, Chinese application 200510041043.5 filed on Jul. 2, 2005, Chinese application 200510041069.X filed on Jul. 5, 2005, Chinese application 200510041070.2 filed on Jul. 5, 2005, Chinese application 200510041275.0 filed on Jul. 18, 2005 and Chinese application 200510041274.6 filed on Jul. 18, 2005. The disclosures of these applications are hereby included by reference herein in their entirety.

### FIELD OF THE INVENTION

The present invention relates to a package structure with flat bumps for electronic device and a method of manufacturing the same, and belongs to the technical field of packaging of electronic devices.

### BACKGROUND OF THE INVENTION

In the traditional leadless flat bond packaging process and structure for integrated circuits or discrete devices, the package is an integral unit cut from an array assembly. The substrate is in the form of a lead frame. The process and structure mainly have the following drawbacks:

1. Special glue film: the special glue film is used to prevent the thermoplastic packaging material from impregnating to the rear part of the lead frame and thereby increasing the risk to insulation of the outer pins during encapsulation under high pressure; however, the special glue film still can't completely prevent overflow of the thermoplastic packaging material. If impregnation of the thermoplastic packaging material still exists, the galvanized coating on the pins may be damaged during post-treatment, and therefore degrades soldering performance. As a result, the material cost, post-treatment cost, and quality will be affected to a certain degree.

2. Palladium plating on both sides of the substrate: in order to ensure the wire soldering process and the manufacture of outer pins can be completed in this process, expensive Pd material is coated on both sides of the lead frame. Therefore, the electroplating cost is high, and the soldering parameters have to be specially set for the material; as a result, the smooth operation of the production line will be affected due to inconsistency of parameters.

3. Contamination: since specific chemical glue film is applied on the lead frame, the solvents in the tape may be gasified under high temperature in different high temperature processes, and will contaminate or cover the pressing area of the chip and the soldering area of the pins, and thereby often causes unstable soldering.

4. Application flexibility of chip and outer pins: limited by the traditional lead frame, the chips and the outer pins have to be arranged in a fixed way; therefore, the application is not flexible.

5. Soldering performance of the outer pins: limited by the traditional lead frame, the outer output pins are flush to the bottom of the molded body, and therefore are difficult to solder to the printed circuit board. As a result, the soldering strength is low.

6. Lead frame: since the lead frame is manufactured through penetrated etching, the lead frame structure is mild. Therefore, the substrate can't be made of high-purity copper material.

7. Metal wire ball bonding: since a penetrative etching process is used, the back of the substrate has to be coated with glue film to prevent overflow. Since the glue film is soft, the positions of the soldering points may dislocate during wire soldering, which will cause loose contact of the soldering points and severely degrade reliability and production stability of the solder wires.

8. Reliability:

A. Though the chemical glue film is coated, certain material overflow will still exist in the high temperature encapsulation process.

B. Since heavy rework is required in case of material overflow, the encapsulation pressure can't be high. As a result, the thermoplastic encapsulation material will be loose, the water absorption rate will increase, and the density will decrease, which will severely increase the production cost and decrease the qualified rate.

C. The output pin part of the product manufactured through leadless flat bond packaging is flush to the bottom of the molded body or even recessed, bad contact may occur due to the poor coplanarity of the pin surfaces in the surface bonding process. In addition, since the outer pins are recessed on the surface of the molded body, air may be trapped in the recess in the surface bonding process, and therefore causes breaking of the contacts due to gas dilatation under high temperature.

D. Since the output pins are as flat as the bottom of the molded body or even recessed, the tin paste on the pins may bond together and cause short circuit under pressing in the surface bonding process.

E. The inner pins are usually coated with silver coating; however, the silver coating doesn't bond well to the thermoplastic packaging material. As a result, delamination may occur between the thermoplastic packaging material and the silver coating.

F. The outer pins that provide electrical output are usually made of Sn—Pd alloy or pure Sn, which is easily oxidized and therefore affects solderability. Furthermore, the shelf life of the product will be short.

G. Since the outer pins that provide electrical output are usually made of Sn—Pd alloy or pure Sn and the Sn material has a low melting point, the Sn material may be oxidized or even melted under the heat generated from friction with the cutting tool in the cutting process; therefore, the solderability and the stability of electrical output of the outer pins will be severely degraded.

9. Heat dissipation capability and conductivity: since the lead frame manufactured through leadless flat bond packaging process employs fully etched copper alloy, the conductivity/heat dissipation capability is only about 65%. If pure copper is used, the conductivity/heat dissipation capability can be at least 90%. However, since pure copper is too soft, high-purity copper can be used in the fully etched lead frame that is very low in structure rigidity to improve heat dispersion capability and electrical conductivity.

### BRIEF SUMMARY OF THE INVENTION

### Technical Problem

To overcome above drawbacks, the present invention provides a package structure with flat bumps for electronic device and the packaging method, which are featured with high solderability, high product reliability, high quality, low cost, smooth production, wide applicability, flexible arrangement of chips, flexible arrangement of pins/pin positions, free of loose soldering points in inner pins or overflow of the thermoplastic encapsulation material, etc.

### Technical Solution

The package structure with flat bumps for electronic device provided in the present invention comprises a chip support base, a lead support base, a chip, metal wires, and a molded body; wherein, the lead support base is arranged adjacent to the chip support base, the chip is mounted on the chip support base and is connected to the lead support base through metal wires, the molded body covers the upper part and the sides of the chip support base and the lead support base, and the lower parts of the chip support base and lead support base protrude from the molded body. In such a package body for electronic device, one or more chip support base islands can be arranged, and the lead pins can be arranged on one side, two sides, or three sides of the island, or around the island, to form a structure with one or more rows of lead pins.

The following options are available for the structure:

The parts of said chip support base protruding from the surface of the molded body, that is the bottom and side surfaces are covered by the molded body. The parts of the lead support base protruding from the surface of the molded body, that is the bottom and side surfaces are covered by the metal layer;

The parts of said chip support base protruding from the surface of the molded body, that is the bottom and side surfaces are covered by the molded body. The front surface of the lead support base is arranged with a metal layer, and the lead pins protruding from the surface of the molded body, that is the bottom and side surfaces, are covered by the metal layer;

The front surface of said chip support base is arranged with a metal layer, and the parts of the island protruding from the surface of the molded body, that is the bottom and side surfaces of the chip support base are covered by the metal layer. The front surface of the lead support base is arranged with a metal layer, and the lead pins protruding from the surface of the molded body, that is the bottom and side surfaces of the lead support base are covered by the metal layer.

An active substance is arranged between the metal layer and the chip support base or lead support base. A bonding substance is arranged between the chip support base and the chip. Said metal layer is made of Au, Ag, Cu, Sn, Ni, or Ni—Pd. The metal wires are gold wires, silver wires, copper wires, or aluminum wires. Said active substance is Ni, Pd, or Ni—Pd.

The procedures of the packaging method for the package structure with flat bumps for electronic device are:

1) Take a packaging substrate with flat bumps;

2) Implant a chip on the front side of the chip support base on the packaging substrate with flat bumps, to fabricate a semi-finished product of an array or assembly of integrated circuits or discrete devices;

3) Carry out metal wiring for the semi-finished product after chip implantation, that is, connect the chip to the corresponding pins on the lead support base, or connect the chip to the corresponding pins on the chip support base and the lead support base;

4) Encapsulate the front side of the semi-finished product after metal wiring in a molded body, and then cure the molded body;

5) Coat a film coating layer on the packaging substrate with flat bumps;

6) Remove the film coating on the rear part of the packaging substrate with flat bumps partially, that is, remove the film coating on the back of the metal layer between the pins and between the pins and the island, so as to expose the area to be etched on the back subsequently;

7) Etch the area where the film coating is removed in the previous procedure, to separate the pins from each other and separate the pins from the island, and form a structure with bumps protruding from the molded body;

8) Remove the film coating on the back of the island and the pins on the packaging substrate with flat bumps, so as to expose the area to be coated with metal subsequently;

9) Coat a metal layer on the surfaces, that is bottom surface and side surfaces of the island and the pins exposed outside of the molded body;

10) Coat a glue film on the front of the molded body;

11) Cut the semi-finished product coated with glue film, to separate the integrated circuits or discrete devices that were connected in an array or assembly.

In above procedures, a bonding substance can be coated on the front of the chip support base before the chip is implanted. Print the semi-finished product on the front after encapsulation in the molded body and curing of the molded body. An active substance can be coated before the metal coating layer is coated.

### Beneficial Results:

1. Metal substrate: since the metal substrate is fabricated through a semi-etching process, the metal substrate structure is relatively rigid. Therefore, the substrate can be made of high-purity copper.

2. Chemical glue film: since the substrate is fabricated through a semi-etching process, no material overflow will occur during the encapsulation process, and no glue film will be needed to prevent overflow. Therefore, the product quality can be improved, and the production cost can be reduced.

3. Contamination: since material overflow can be prevented in the encapsulation process without any chemical glue film, no contamination related to the glue film will occur. Therefore, the production will be smooth, the qualified rate will be higher, and the cost will be low.

4. Metal wire soldering: since a metal substrate fabricated through a semi-etching process is used, the inner pins and the metal substrate are in an integral structure, and the positions of the inner pins will be stable in the wiring process, and thereby no loose pin soldering point will occur. As a result, the production will be more smooth.

5. Solderability of outer pins: in the package structure with flat bumps, the outer output pins protrude from the bottom of the molded body; therefore, the outer pins in the form of bumps can be soldered more easily and firmly to the printed circuit board. Moreover, the twice etching process ensures absolute coplanarity between the outer pins and makes the manufacturer worry free about instability of surface bonding; therefore, compared to the traditional leadless flat bond packaging structure, this product is superior in quality.

6. Reliability

A. No material overflow will occur during encapsulation with the molded body.

B. Since a semi-etching process is used, no material overflow will occur even if higher pressure is used in the encapsulation process. Therefore, the product reliability is ensured, and the production will be more smoothly, and the cost will be reduced.

C. Since the output pins on the bottom of the molded body protrude from the molded body, the residual Sn paste will attach around the pins. Therefore, short circuit in the Sn paste can be avoided, and the bonding strength of the outer pins in the form of bumps will be increased.

D. The inner pins in the wiring area are coated with Au, Ni, or Ni—Pd instead of Ag. Due to the fact that the bonding strength between the encapsulation material and Au, Ni, or Ni—Pd is much higher than that between the capsulation and Ag, no delamination will occur;

E. Since the coating material is an inert material when the outer pins that provide electrical output are coated with Au, Ni, or Ni—Pd, it will not be oxidized in the ambient gas or due to the temperature factor. Therefore, the shield life of the product will be very long;

F. Since the coating material is an inert metal material with a high melting point when the outer pins that provide electrical output are coated with Au, Ni, or Ni—Pd, the coating on the outer pins will not be oxidized under the heat resulted from friction in the cutting process. Therefore, the solderability and the stability of electrical transmission of the output pins are ensured, and the product quality is improved.

7. Heat dissipation capability and conductivity: since the package metal substrate with flat bumps is fabricated through a semi-etching process, the structural strength of the substrate is significantly higher than any lead frame fabricated through a penetrative etching process; therefore, the metal substrate can be made of high-purity copper material, so as to improve heat dissipation and electrical transmission performance.

### BRIEF DESCRIPTION OF THE DRAWINGS

These, and other objects, features and advantages of this invention will become apparent from the following detailed description of the various aspects of the invention taken in conjunction with the accompanying drawings, in which:

FIGS. 1-13 are schematic diagrams of the procedures of the packaging method provided in the present invention. Wherein, FIG. 13 is a schematic diagram of a package structure with single bump, in which an active substance 6 is arranged between the metal layer and the chip support base 1 or lead support base 2, and a metal layer 7 is coated on the active substance 6.

FIG. 14 is a schematic diagram of a structure in which part of the island and pins protruding from the molded body, that is the bottom and side surfaces of the said island and pins are coated with a metal layer.

FIG. 15 is a schematic diagram of a structure in which the pins are arranged around an island; wherein, FIG. 15b is a sectional view of the structure shown in FIG. 15a.

FIG. 16 is a schematic diagram of a structure in which the pins are arranged around a plurality of islands; wherein, FIG. 16b is a sectional view of the structure shown in FIG. 16a.

FIG. 17 is a schematic diagram of a structure in which multiple rows of pins are arranged around an island; wherein, FIG. 17b is a sectional view of the structure shown in FIG. 17a.

FIG. 18 is a schematic diagram of a structure in which two rows of pins are arranged on both sides of an island; wherein, FIG. 18b is a sectional view of the structure shown in FIG. 18a.

FIG. 19 is a schematic diagram of a structure in which multiple rows of pins are arranged on both sides of an island; wherein, FIG. 19b is a sectional view of the structure shown in FIG. 19a.

FIG. 20 is a schematic diagram of a structure in which a row of pins are arranged around a plurality of islands; wherein, FIG. 20b is a sectional view of the structure shown in FIG. 20a.

Brief description of the reference numbers: 1—Chip support base; 2—Lead support base; 3—Chip; 4—Metal wire; 5—Molded body; 6—Active substance; 7—Active substance; 8—Semi-etching area.

### DETAILED DESCRIPTION OF THE PREFERRED EMBODIMENTS

The package structure with flat bumps for electronic device provided in the present invention comprises a chip support base 1, a lead support base 2, a chip 3, metal wire 4, and a molded body 5, wherein the lead support base 2 is arranged adjacent to the chip support base 1, the chip 3 is mounted on the chip support base 1, the chip 3 is connected with the lead support base 1 through the metal wires 4, the molded body 5 covers the upper part and side parts of the chip support base 1 and lead support base 2 and makes the lower parts of chip support base 1 and lead support base 2 protrude from the molded body 5. It is possible to arrange one or more islands in such a package body for electronic device. The pins can be arranged on one side, two sides, or three sides of the island, or around the island to form a structure with one or more rows of pins.

The following options are available for the structure:

Part of the said chip support base protruding from the molded body, that is the bottom and side surfaces of the said chip support base are covered by the metal layer. Part of the lead support base protruding from the molded body, that is bottom and side surfaces of the said lead support base are covered by the metal layer.

Part of said chip support base protruding from the molded body, that is bottom and side surfaces of the chip support base, are covered by a metal layer. A metal layer is arranged on the front surface of the lead support base, and part of the pins protruding from the molded body, that is bottom and side surfaces of the said pins are covered by the metal layer.

The front surface of said chip support base is provided with a metal layer, and part of the island protruding from the surface of the molded body, that is the bottom and side surfaces of the said island are covered by the metal layer. The front surface of the lead support base is provided with a metal layer, and part of the lead pins protruding from the surface of the molded body, that is the bottom and side surfaces, of the said lead pins are covered by the metal layer.

An active substance 6 is provided between the metal layer and the chip support base 1 or lead support base 2. A bonding substance is provided between the chip support base 1 and the chip 3. Said metal layer select form the group of Au, Ag, Cu, Sn, Ni, or Ni—Pd. The metal wires 4 select form the group of gold wires, silver wires, copper wires, or aluminum wires. Said active substance 6 selects form Ni, Pd, or Ni—Pd.

The encapsulation process provided in the present invention comprises the following procedures:

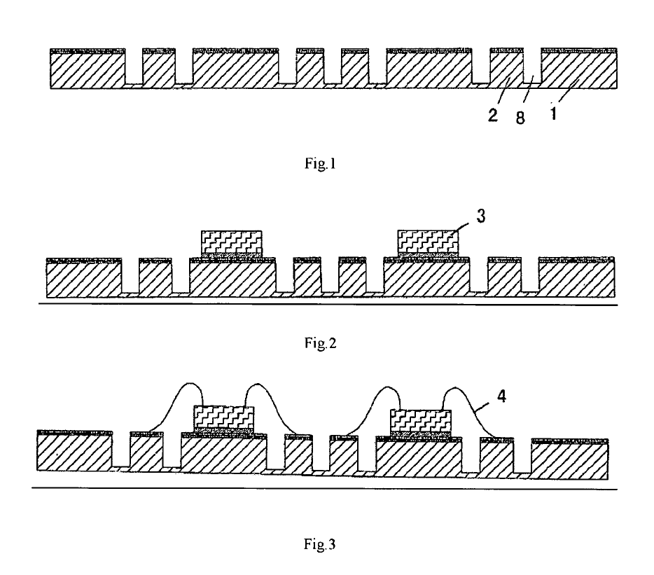

1) Taking a substrate with flat bumps, as shown in FIG. 1: apply Silver Adhesive (conductive adhesive/non-conductive adhesive) on the front metal layer 7 in the chip area. If an eutectic model is to be used, no silver adhesive will be needed.

2) Bonding operation—as shown in FIG. 2: implant a chip 3 into the metal layer 7 on the chip support base 1 on the front of the substrate with flat bumps, to fabricate a semi-finished product of an array or assembly of integrated circuits or discrete devices.

3) Metal wire ball bonding—as shown in FIG. 3: carry out metal wiring with the metal wires 4 for the semi-finished product after chip implantation, that is, connect the chip 3 to the corresponding pins on the lead support base 2. The metal wires can be gold wires, silver wires, copper wires, or aluminum wires.

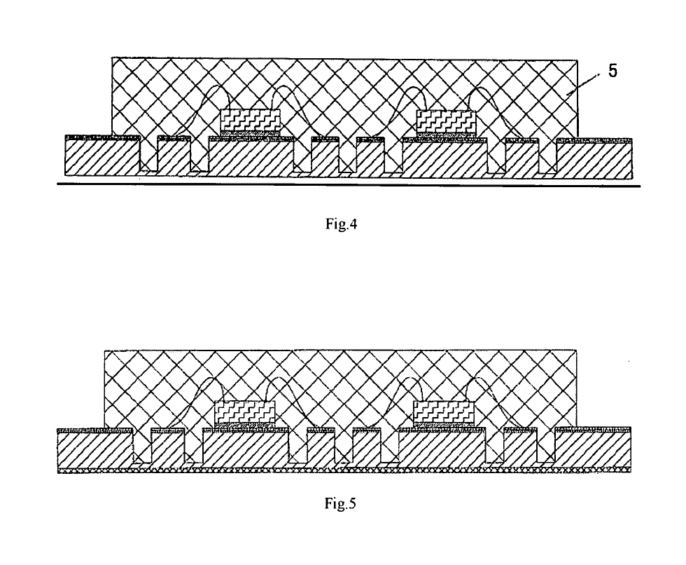

4) Encapsulation—as shown in FIG. 4: encapsulate the front part of the semi-finished product after wiring into a molded body 5, and then cure the molded body 5 in accordance with the characteristic of the packaging material, so as to ensure safety of the metal wires, chip, and inner pins.

5) Printing: print on the front of the semi-finished product after encapsulation and curing, to identify the functions and characteristics of the chip.

6) Film coating—as shown in FIG. 5: coat a film coating on the bottom of the substrate with flat bumps.

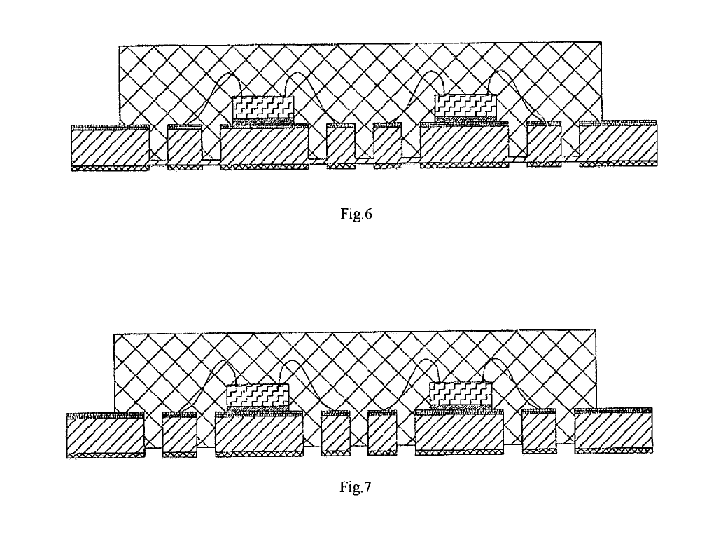

7) Removing undesired film—as shown in FIG. 6: remove the film coating in the semi-etching area 10 on the bottom of the substrate with flat bumps, to expose the area to be etched subsequently.

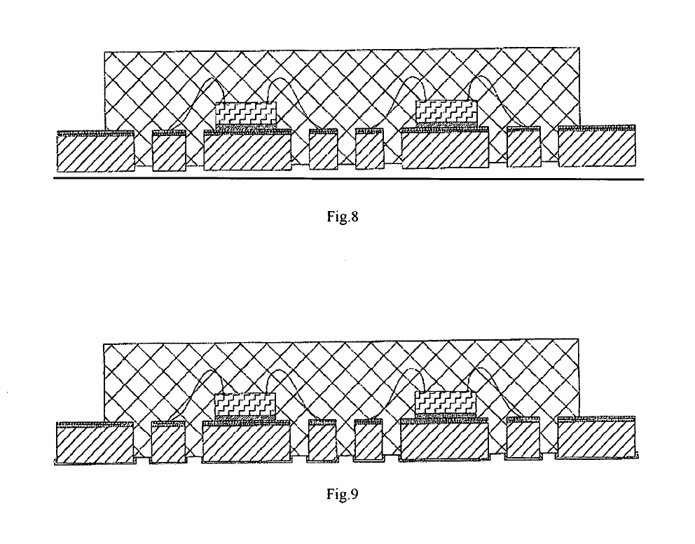

8) Etching on the back of the substrate—as shown in FIG. 7: etch the metal in the area that is not covered by the film (i.e., the semi-etching area 10), so as to make the lower parts of chip support base 1 and lead support base 2 protrude from the molded body 5.

9) Removing the residual film on the back of the substrate with flat bumps—as shown in FIG. 8: remove the residual film on the back of the substrate, so as to carry out the subsequent electroplating process.

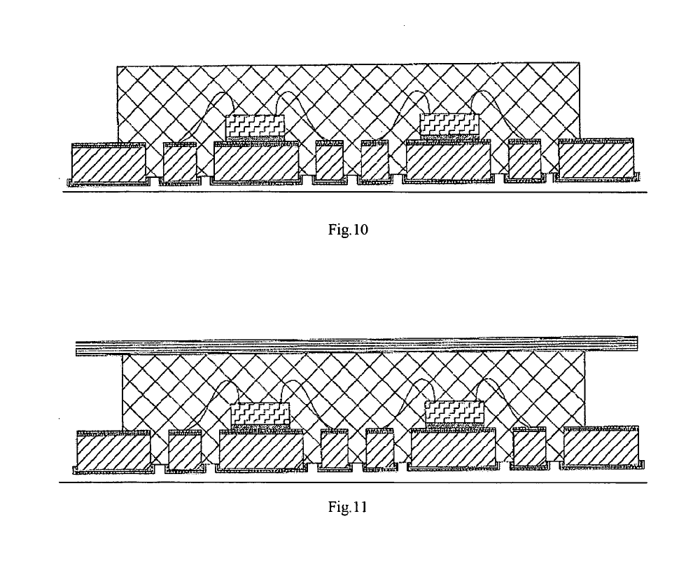

10) Electroplating—as shown in FIG. 9: coat the active substance on the chip support base 1 and the lead support base protruding from the molded body 5.

11) Electroplating—as shown in FIG. 10: coat a metal layer (e.g., Au, Ag, Cu, Sn, Ni, or Ni—Pd) on the active substance, so that the exposed parts of the pins on the chip support base 1 and lead support base 2 are coated with an inert metal layer.

12) Film bonding on the molded body—as shown in FIG. 11: after coating the pins with a metal layer, bond a glue film on the semi-finished molded body, and prepare for the subsequent glue film cutting operation.

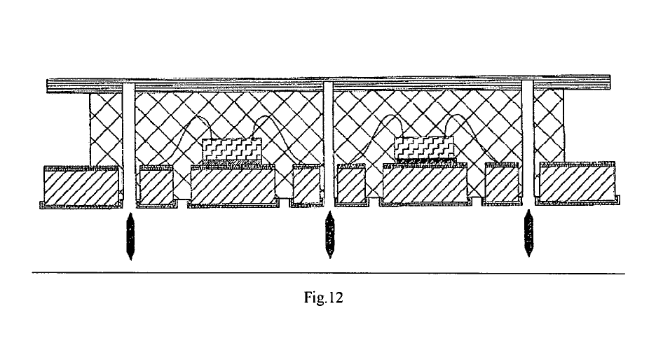

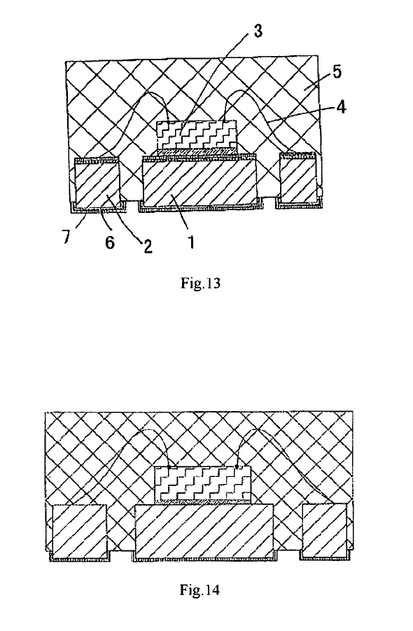

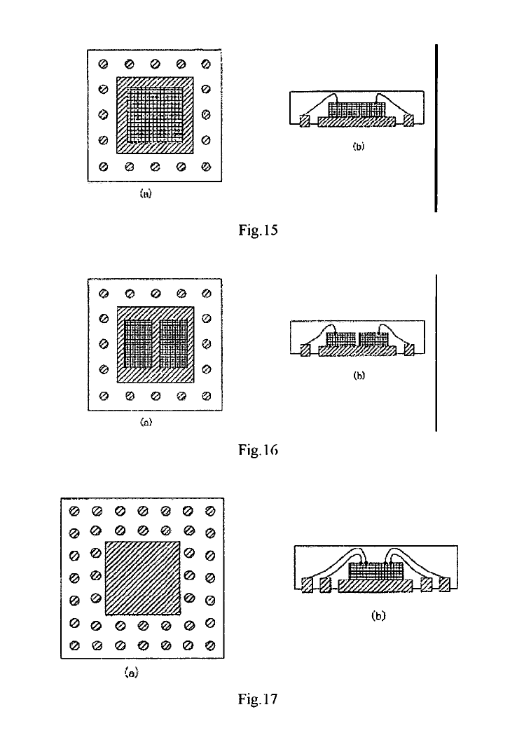

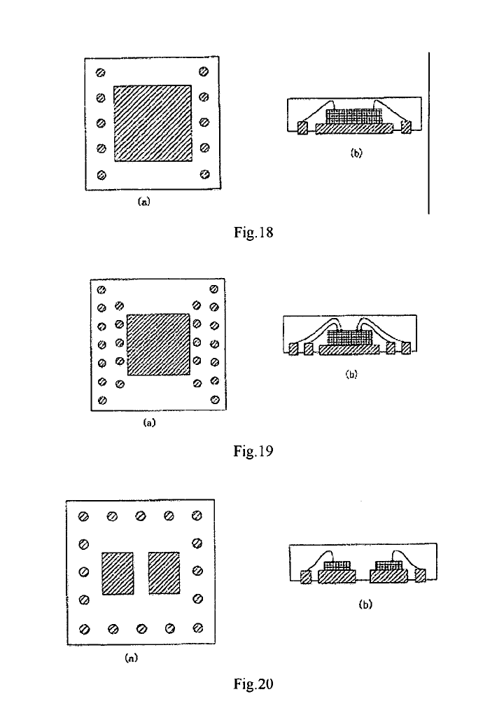

13) Cutting molded body—as shown in FIG. 12: cut the semi-finished product coated with the glue film, so as to separate the chips that were originally connected in an array or assembly from each other.

14) Separating the molded body from the glue film: separate the molded body encapsulating the integrated circuit or discrete device from the glue film with a handling tool, and place the molded body on a plastic tray or in a plastic rubber tube or braid.

1. A package structure with flat bumps for electronic device, comprising a chip support base, a lead support base, a chip, metal wires, and a molded body, wherein the lead support base is arranged adjacent to the chip support base, the chip is mounted on the chip support base and is connected to the lead support base through metal wires, the molded body covers the upper part and side parts of the chip support base and the lead support base, and makes the lower parts of chip support base and lead support base protrude from the molded body; in such a package structure for electronic device, one or more chip support base islands are arranged, and the lead pins can be arranged on one side, two sides or three sides of the island, or around the island, to form a structure with one or more rows of lead pins.

2. The package structure with flat bumps for electronic device according to claim 1, wherein part of said chip support base protruding from the molded body, that is bottom and side surfaces of the said chip support base are covered by a metal layer; part of said lead support base protruding from the molded body, that is bottom and side surfaces of the said lead support are covered by a metal layer.

3. The package structure with flat bumps for electronic device according to claim 1, wherein part of said chip support base protruding from the molded body, that is bottom and side surfaces of the said chip support base are covered by a metal layer; the front side of said lead support base is coated with a metal layer, and part of said lead support base protruding from the molded body, that is bottom and side surfaces, of the said lead support are covered by a metal layer.

4. The package structure with flat bumps for electronic device according to claim 1, wherein the front side of said chip support base is coated with a metal layer, and part of the said chip support base protruding from the molded body, that is bottom and side surfaces of the said chip support base are covered by a metal layer; the front side of said lead support base is coated with a metal layer, and part of said lead support base protruding from the molded body, that is bottom and side surfaces of the said lead support base are covered by a metal layer.

5. The package structure with flat bumps for electronic device according to claim 2 wherein an active substance is provided between the metal layer and the chip support base or lead support base.

6. The package structure with flat bumps for electronic device according to claim 1, wherein a bonding substance is provided between the chip support base and the chip.

7. The package structure with flat bumps for electronic device according to claim 2, wherein the said metal layer is select form the group of Au, Ag, Cu, Sn, Ni, or Ni—Pd.

8. The package structure with flat bumps for electronic device according to claim 2, wherein the said metal layer can cover the front part of the chip support base or the entire chip support base.

9. The package structure with flat bumps for electronic device according to claim 1, wherein the said metal wires are gold wires, silver wires, copper wires, or aluminum wires.

10. The package structure with flat bumps for electronic device according to claim 5, wherein the said active substance is Ni, Pd, or Ni—Pd.

11. A method of manufacturing the package structure with flat bumps for electronic device according to claim 1, wherein the said method comprises the following packaging procedures:
1) taking a packaging substrate with flat bumps;
2) implanting a chip on the front side of the chip support base on the packaging substrate with flat bumps, to fabricate a semi-finished product of an array or assembly of integrated circuits or discrete devices;
3) carrying out metal wiring with the metal wires for the semi-finished product after chip implantation, that is, connect the chip to the corresponding pins on the lead support base, or connect the chip to the corresponding pins on the chip support base and lead support base.
4) encapsulating the front side of the semi-finished product after metal wiring in a molded body, and then curing the molded body;
5) coating a film coating layer on the packaging substrate with flat bumps;
6) removing the film coating on the back of the packaging substrate with flat bumps partially, that is, remove the film coating on the back of the metal layer between the pins and between the pins and the island, so as to expose the area to be etched on the island, and
7) etching the area where the film coating is removed in the previous procedure, to separate the pins from each other and separate the pins from the island, and form a structure with bumps protruding from the molded body;
8) removing the film coating on the back of the island and the pins on the packaging substrate with flat bumps, so as to expose the area to be coated with metal subsequently;
9) coating a metal layer on the surfaces (i.e., bottom surface and side surfaces) of the island and the pins exposed outside of the molded body;
10) coating a glue film on the front of the molded body;
11) cutting the semi-finished product coated with glue film, to separate the integrated circuits or discrete devices that were connected in an array or assembly.

12. The method of manufacturing the package structure with flat bumps for electronic device according to claim 11, wherein a bonding substance is coated on the front of the chip support base before the chip is implanted.

13. The method of manufacturing the package structure with flat bumps for electronic device according to claim 11, wherein printing is carried out on the front of the semi-finished product after the product is encapsulated in the molded body and the molded body is cured.

14. The method of manufacturing the package structure with flat bumps for electronic device according to claim 11, wherein an active substance is coated before the metal layer is coated.
